(19) United States
(12) Patent Application Publication
(10) Pub. No.: US 2010/0072526 A1
(43) Pub. Date: Mar. 25, 2010

(54) SEMICONDUCTOR MEMORY DEVICE

(75) Inventors: Yoshinori Kumura, Albany, CA (US); Hiroyuki Kanaya, Yokohama-shi (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/554,396

(22) Filed: Sep. 4, 2009

(30) Foreign Application Priority Data
Sep. 24, 2008 (JP) 2008-244576

(51) Int. Cl. H01L 29/92; H01L 21/02

(52) U.S. Cl. 257/295; 438/3; 257/E29.342; 257/E21.008

(57) ABSTRACT

A semiconductor memory device includes a semiconductor substrate; a ferroelectric capacitor comprising an upper electrode, a ferroelectric film, and a lower electrode above the semiconductor substrate; and an upper interlayer dielectric film surrounding a periphery of the ferroelectric capacitor, wherein a gap is provided between the ferroelectric capacitor and the upper interlayer dielectric film.

### CROSS-REFERENCE TO RELATED APPLICATION

This application is based upon and claims the benefit of priority from the prior Japanese Patent Applications No. 2008-244576, filed on Sep. 24, 2008, the entire contents of which are incorporated herein by reference.

### BACKGROUND OF THE INVENTION

1. Field of the Invention

The present invention relates to a semiconductor memory device.

2. Related Art

Ferroelectric random access memories have been attracted attention as one of nonvolatile semiconductor memories. Because polarization characteristics of ferroelectric capacitors become inferior by a reduction action of hydrogen, hydrogen barrier films are utilized frequently for protecting the ferroelectric capacitors from hydrogen.

The polarization characteristics of the ferroelectric capacitors are deteriorated by stresses from materials contacting the ferroelectric capacitors. For example, such stresses are caused by various materials such as materials for the ferroelectric capacitors (PZT, Ir, IrO₂), interlayer films (TEOS), hydrogen barrier films (Al₂O₃, SiN), and metallic interconnections (Ti, TiN, Al, W). According to downscaling of the ferroelectric capacitors, the deterioration of the polarization characteristics of the ferroelectric capacitors due to stresses becomes more serious than before.

### SUMMARY OF THE INVENTION

A semiconductor memory device according to an embodiment of the present invention comprises: a semiconductor substrate; a ferroelectric capacitor comprising an upper electrode, a ferroelectric film, and a lower electrode above the semiconductor substrate; and an upper interlayer dielectric film surrounding a periphery of the ferroelectric capacitor, wherein a gap is provided between the ferroelectric capacitor and the upper interlayer dielectric film.

A method of manufacturing a semiconductor memory device according to an embodiment of the present invention comprises: forming a transistor on a semiconductor substrate; forming a lower interlayer dielectric film covering the transistor; forming a first contact plug passing through the lower interlayer dielectric film to be connected to the transistor; forming a ferroelectric capacitor comprising an upper electrode, a ferroelectric film, and a lower electrode on the first contact plug; forming a first hydrogen barrier film on side and top surfaces of the ferroelectric capacitor; depositing a first upper interlayer dielectric film on the first hydrogen barrier film; etching the first upper interlayer dielectric film in such a manner that a trench is formed around the ferroelectric capacitor; burying a sacrificial layer in the trench; depositing a second upper interlayer dielectric film on the sacrificial layer; forming a contact hole passing through the second upper interlayer dielectric film, the sacrificial layer, and the first hydrogen barrier film to reach the upper electrode; removing the sacrificial layer selectively through the contact hole to form a gap between the first hydrogen barrier film and the first and the second upper interlayer dielectric films; and forming a contact plug closing an opening of the gap.

A method of manufacturing a semiconductor memory device according to an embodiment of the present invention comprises: forming a transistor on a semiconductor substrate; forming a lower interlayer dielectric film covering the transistor; forming a first contact plug passing through the lower interlayer dielectric film to be connected to the transistor; forming a ferroelectric capacitor comprising an upper electrode, a ferroelectric film, and a lower electrode on the first contact plug; forming a sacrificial layer on side and top surfaces of the ferroelectric capacitor; depositing the first hydrogen barrier film on the sacrificial layer; depositing an upper interlayer dielectric film on the first hydrogen barrier film; forming a contact hole passing through the upper interlayer dielectric film, the first hydrogen barrier film, and the sacrificial layer to reach the upper electrode; removing the sacrificial layer selectively through the contact hole to form a gap between a side surface of the ferroelectric capacitor and the first hydrogen barrier film; and forming a contact plug closing an opening of the gap.

### BRIEF DESCRIPTION OF THE DRAWINGS

FIG. 1 is a circuit diagram showing a configuration of a ferroelectric random access memory according to embodiments of the present invention;

FIG. 2 is a cross-sectional view showing a configuration of a ferroelectric capacitor according to a first embodiment of the present invention;

FIGS. 3 to 14 are cross-sectional views showing a manufacturing method of the ferroelectric capacitor FC according to the first embodiment;

FIG. 15 is a cross-sectional view showing a configuration of a ferroelectric capacitor according to a second embodiment of the present invention;

FIGS. 16 and 17 are cross-sectional views showing a manufacturing method of the ferroelectric capacitor FC according to the second embodiment;

FIG. 18 is a cross-sectional view showing a configuration of a ferroelectric capacitor according to a third embodiment of the present invention;

FIGS. 19 to 23 are cross-sectional views showing a manufacturing method of the third embodiment;

FIG. 24 is a cross-sectional view showing a configuration of a ferroelectric capacitor according to a fourth embodiment of the present invention; and

FIGS. 25 to 28 are cross-sectional views showing the ferroelectric capacitors FC that are adjacent to each other in the direction the word line WL extends and share the gap 50 for the first to fourth embodiments, respectively.

### DETAILED DESCRIPTION OF THE INVENTION

Embodiments of the present invention will be explained below in detail with reference to the accompanying drawings. Note that the invention is not limited thereto.

### First Embodiment

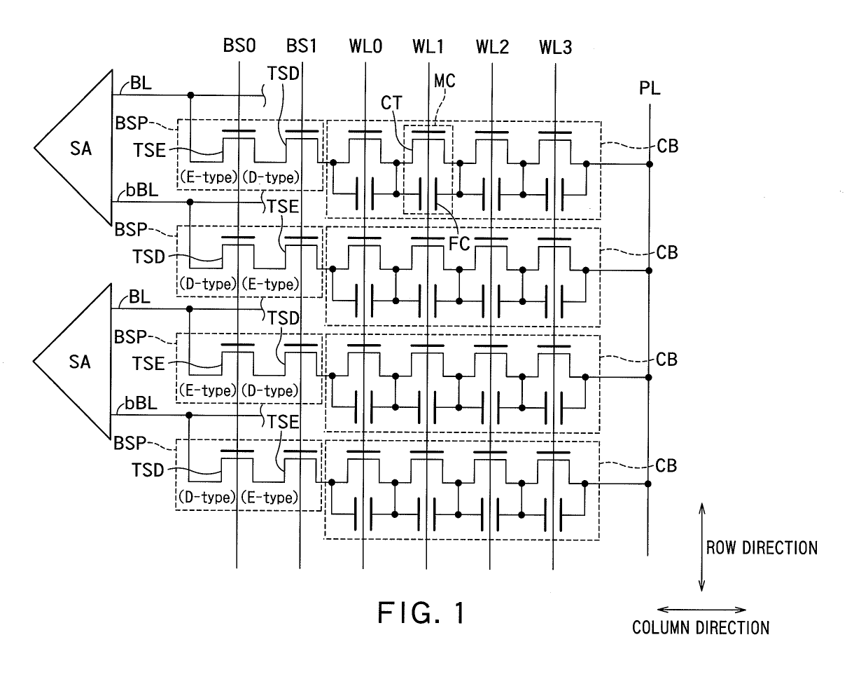

FIG. 1 is a circuit diagram showing a configuration of a ferroelectric random access memory according to embodiments of the present invention. The ferroelectric random access memory of the embodiments is a “series connected TC unit type ferroelectric RAM”. The series connected TC unit type ferroelectric RAM consists of series connected memory cells each having a transistor having a source terminal and a drain terminal and a ferroelectric capacitor inbetween said two terminals.

The ferroelectric random access memory of the embodiments includes a plurality of word lines WLi (i is an integer) extending in a row direction, a plurality of bit lines BL and bBL extending in a column direction perpendicular to the row direction, a plurality of plate lines PL extending in the row direction, and block selectors BSP.

A memory cell MC stores binary data or multi-bit data in a ferroelectric capacitor. Each memory cell MC is provided at an intersection of the word line WLi and the bit line BL or bBL. Each word line WLi is connected to gates of cell transistors CT arranged in the row direction. Each bit line BL or bBL is connected to sources or drains of cell transistors CT arranged in the column direction.

The ferroelectric random access memory includes a plurality of cell blocks CB each of which is configured by connecting serially the memory cells MC each including the ferroelectric capacitor FC and the cell transistor CT connected in parallel. One ends of the cell blocks CB are connected to one ends of the block selectors BSP. The other ends of the cell blocks CB are connected to the plate lines PL. The other ends of the block selectors BSP are connected to either the bit lines BL or bBL. Namely, the bit lines BL and bBL are connected via the corresponding block selectors BSP to the cell blocks CB.

The block selector BSP includes an enhancement transistor TSE and a depletion transistor TSD. The enhancement transistor TSE and the depletion transistor TSD are controlled by a block selective line BS0 or BS1. Thus, the block selector BSP can connect one of the paired bit lines BL and bBL selectively to the bit line BL or bBL.

A sense amplifier SA is connected to the bit line pair BL, bBL. The sense amplifier SA detects data from the memory cells transmitted through the bit line pair BL, bBL during data reads. The sense amplifier SA applies voltage to the bit line pair BL, bBL during data writes to write data in the memory cells MC. The present embodiments can be operated in a 1T1C mode or a 2T2C mode.

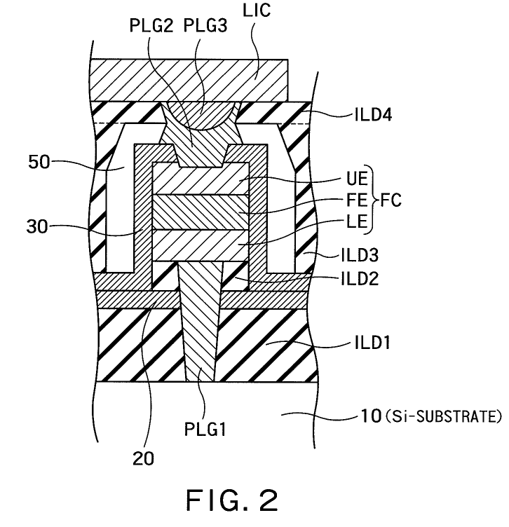

FIG. 2 is a cross-sectional view showing a configuration of a ferroelectric capacitor according to a first embodiment of the present invention. Only the ferroelectric capacitor is shown in FIG. 2 and the cell transistor is omitted.

The ferroelectric random access memory of the first embodiment is formed on a silicon substrate 10. The cell transistor (not shown in FIG. 2) is provided on the silicon substrate 10. A lower interlayer dielectric film ILD1 is provided on the silicon substrate 10 so as to cover the cell transistor. Hydrogen barrier films 20 and 30 are provided on the lower interlayer dielectric film ILD1. A middle interlayer dielectric film ILD2 is provided between the hydrogen barrier film 20 and a ferroelectric capacitor FC. A first contact plug PLG1 is provided so as to pass through the middle interlayer dielectric film ILD2, the hydrogen barrier film 20, and the lower interlayer dielectric film ILD1 for reaching the silicon substrate 10.

The ferroelectric capacitor FC is provided on the first contact plug PLG1 and the middle interlayer dielectric film ILD2. The ferroelectric capacitor FC is provided on the first contact plug PLG1 in this way and the first contact plug PLG1 connects between a lower electrode LE and the cell transistor. Such a configuration is called COP (Capacitor On Plug) structure.

The ferroelectric capacitor FC includes the lower electrode LE, a ferroelectric film FE, and an upper electrode UE. The hydrogen barrier film 30 is formed on the hydrogen barrier film 20 and on a side surface of the ferroelectric capacitor FC. Upper interlayer dielectric films ILD3 and ILD4 are provided on the hydrogen barrier film 30 so as to surround a periphery of the ferroelectric capacitor FC. A gap 50 is formed between the side surface of the ferroelectric capacitor FC and the upper interlayer dielectric films ILD3 and ILD4. In the first embodiment, the gap 50 is provided between the hydrogen barrier film 30 and the upper interlayer dielectric films ILD3 and ILD4.

The hydrogen barrier film 30 is also provided on the upper electrode UE of the ferroelectric capacitor FC. A part of the hydrogen barrier film 30 is open and a second contact plug PLG2 is filled in the opening. The second contact plug PLG2 is thus connected to the upper electrode UE. The second contact plug PLG2 closes the opening of the gap 50. A third contact plug PLG3 is further provided on the second contact plug PLG2.

A local interconnection LIC is formed on the upper interlayer dielectric film ILD4 and the third contact plug PLG3. The local interconnection LIC is electrically connected via the second and third contact plugs PLG2 and PLG3 to the upper electrode UE. Further, the local interconnection LIC electrically connects the upper electrodes UE of two ferroelectric capacitors adjacent to each other in the bit line direction to either the source or the drain of the cell transistor.

The first contact plug PLG1 electrically connects the lower electrode LE to the other of the source and drain of the cell transistor. The chain FeRAM is thus configured.

No gap was provided around conventional ferroelectric capacitors. In the first embodiment, however, the gap 50 is provided between the side and top surfaces of the ferroelectric capacitor FC and the upper interlayer dielectric films ILD3 and ILD4. Thus, stresses of the upper interlayer dielectric films ILD3 and ILD4 are not applied to the ferroelectric capacitor FC. Even if the hydrogen barrier film 30 around the ferroelectric capacitor FC varies in volume, the gap 50 can absorb the volume variation of the hydrogen barrier film 30. Thus, the stresses applied to the ferroelectric capacitor FC are reduced. As a result, the deterioration of the polarization characteristics of the ferroelectric capacitor FC can be suppressed.

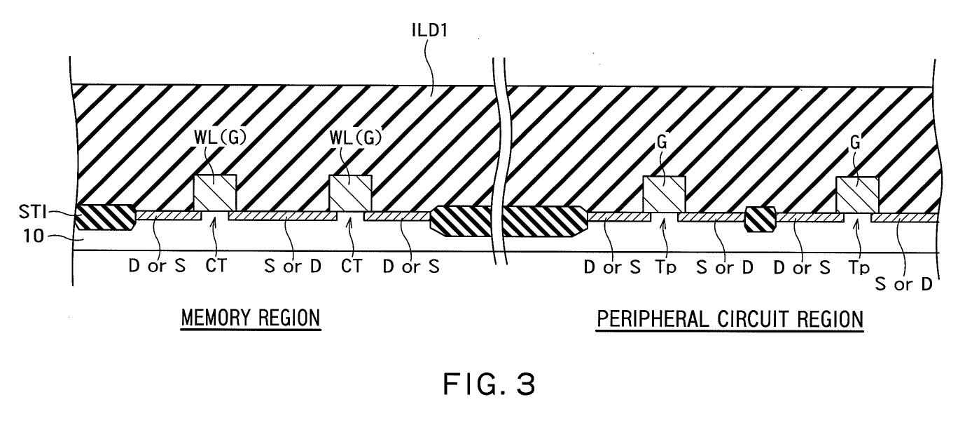

FIGS. 3 to 14 are cross-sectional views showing a manufacturing method of the ferroelectric capacitor FC according to the first embodiment. A memory region and a peripheral circuit region are shown side by side in these drawings.

An STI (Shallow Trench Isolation) is first formed on the silicon substrate 10 for isolation. As shown in FIG. 3, the cell transistor CT is formed on the silicon substrate 10 in the memory region. A transistor Tp is formed on the silicon substrate 10 in the peripheral circuit region. The cell transistor CT and the transistor Tp are preferably formed at the same time to shorten a manufacturing process. Sizes (W (gate width)/L (gate length)) or channel impurity densities thereof can be different from each other. The word line WL also functions as a gate electrode G of the cell transistor CT.

The lower interlayer dielectric film ILD1 is then deposited so as to cover the cell transistor CT and the transistor Tp. The lower interlayer dielectric film ILD1 is flattened by CMP (Chemical-Mechanical Polishing). Exemplary materials for the lower interlayer dielectric film ILD1 include BPSG (Boron Phosphorous Silicate Glass) and P-TEOS (Plasma-Tetra Ethoxy Silane). A configuration shown in FIG. 3 is thus obtained.

The hydrogen barrier film 20 is then deposited on the lower interlayer dielectric film ILD1 and the middle interlayer dielectric film ILD2 is further deposited on the hydrogen barrier film 20. Exemplary materials for the hydrogen barrier film 20 include Al₂O₃ and SiN.

Contact holes are then formed so as to pass through the middle interlayer dielectric film ILD2, the hydrogen barrier film 20, and the lower interlayer dielectric film ILD1 for reaching the source or the drain of the cell transistor CT. The contact hole is also formed on the gate electrode G of the transistor Tp.

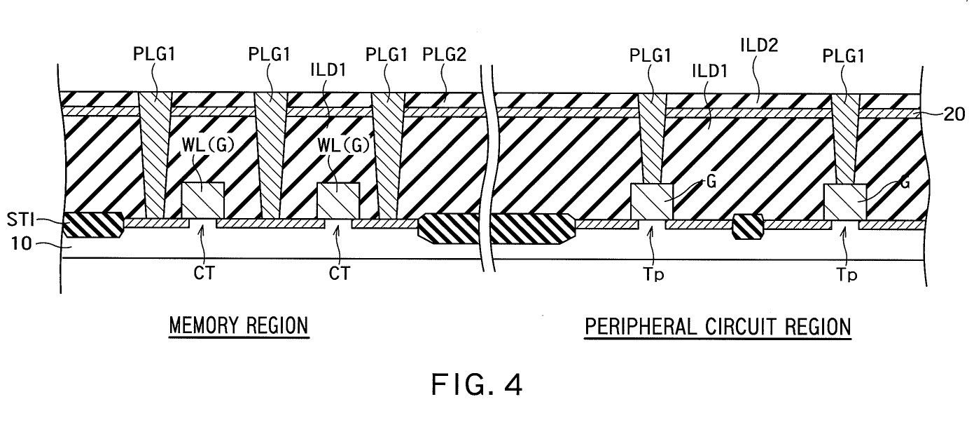

Metal is then buried in the contact holes. Examples of the metal include tungsten and doped polysilicon. The metal is flattened by the CMP, and the first contact plug PLG1 is formed as a result as shown in FIG. 4.

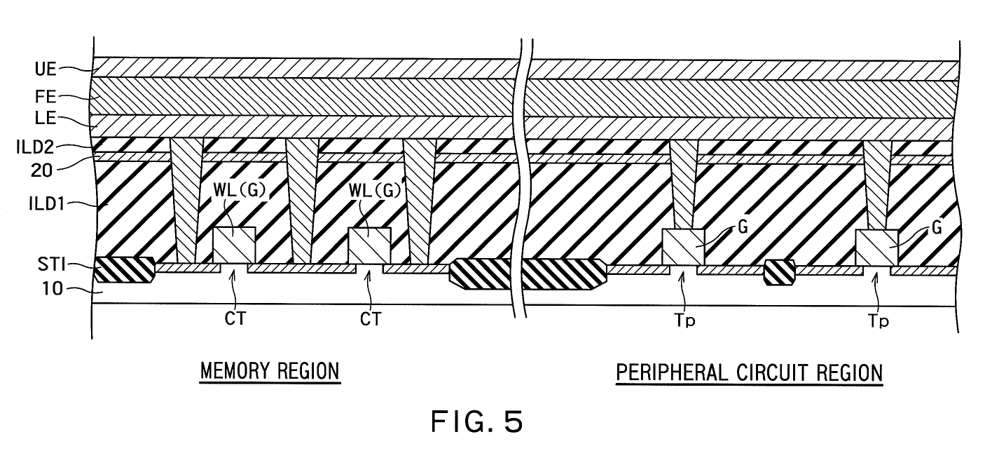

As shown in FIG. 5, materials for the lower electrode LE, the ferroelectric film FE and the upper electrode UE are then deposited in this order on the middle interlayer dielectric film ILD2 and the first contact plug PLG1. The lower electrode LE is made of materials including any of Ti, TiN, TiAlN, Pt, Ir, IrO₂, SRO, Ru, and RuO₂, for example. The ferroelectric film FE is made of materials including any of PZT, and SBT, for example. The upper electrode UE is made of materials including any of Pt, Ir, IrO₂, SRO, Ru, and RUO₂, for example.

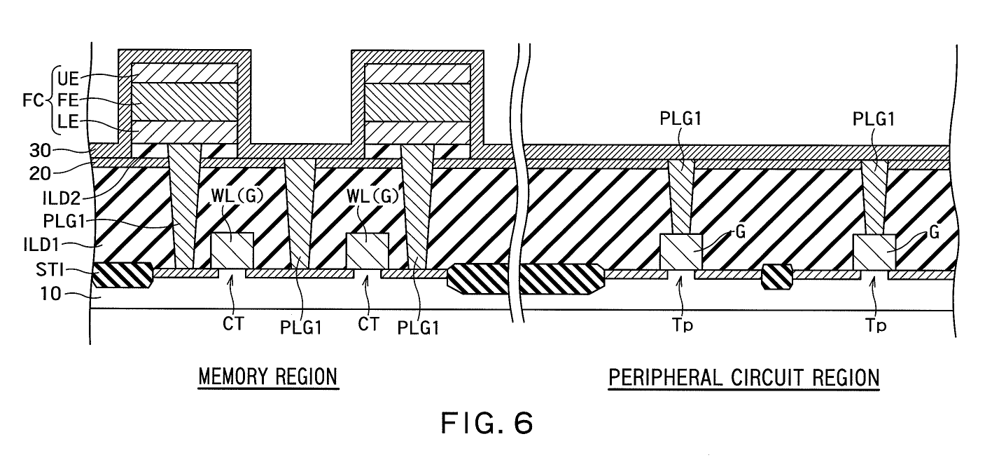

A mask material is then deposited on the upper electrode UE. The mask material is made of, e.g., P-TEOS, O₃-TEOS, or Al₂O₃. The mask material is processed in a pattern of the ferroelectric capacitor FC by lithography and RIE (Reactive Ion Etching). The upper electrode UE, the ferroelectric film FE, and the lower electrode LE are then etched by using the mask material as a mask. As shown in FIG. 6, the ferroelectric capacitor FC is thus formed. Because the hydrogen barrier film 20 acts as an etching stopper, the middle interlayer dielectric film ILD2 is also etched. The hydrogen barrier film 30 is then deposited on the side and top surfaces of the ferroelectric capacitor FC and on the hydrogen barrier film 20. Exemplary materials of the hydrogen barrier film 30 include Al₂O₃ and SiN.

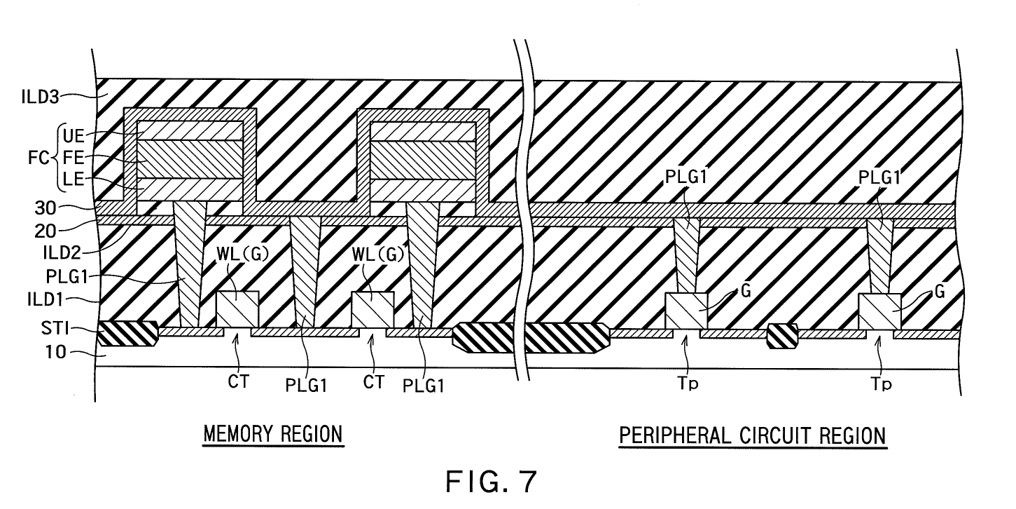

Next, as shown in FIG. 7, the upper interlayer dielectric film ILD3 is deposited on the hydrogen barrier film 30 and then flattened by the CMP. Exemplary materials for the upper interlayer dielectric film ILD3 include P-TEOS, O₃-TEOS, SOG, and a low-k film (SiOF and SiOC).

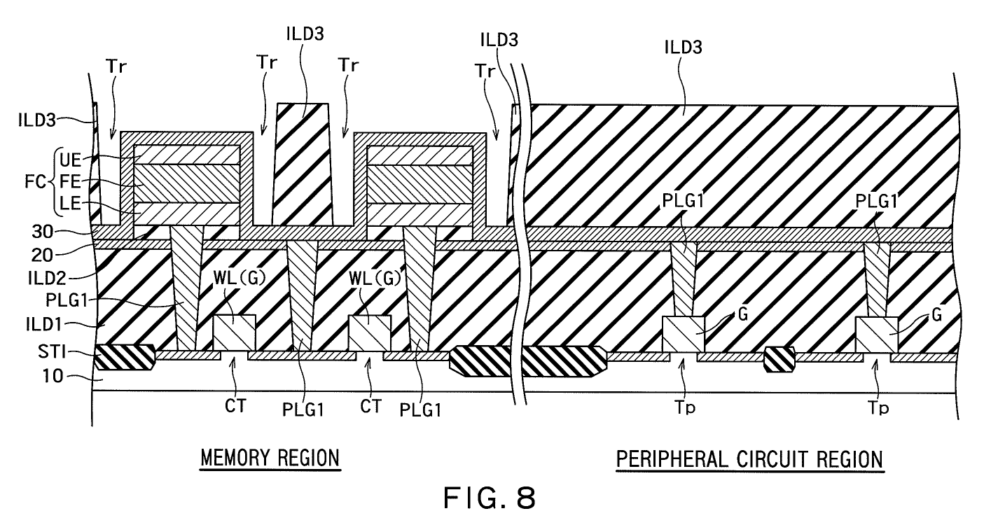

The upper interlayer dielectric film ILD3 is then etched by the lithography and RIE so that a trench Tr is formed around the ferroelectric capacitor FC. As a result, as shown in FIG. 8, the hydrogen barrier film 30 on the top and side surfaces of the ferroelectric capacitor FC is exposed.

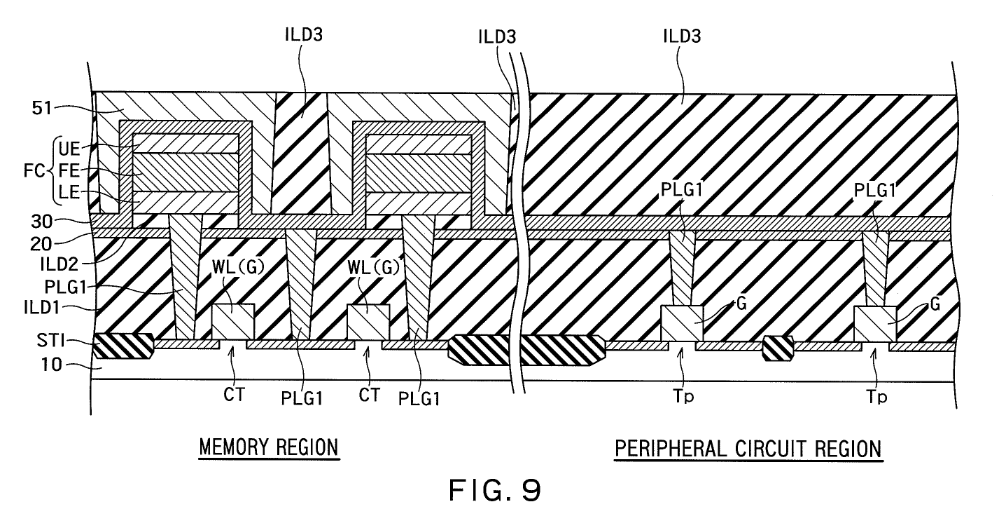

Next, as shown in FIG. 9, a sacrificial layer 51 is buried in the trench Tr and then flattened by the CMP. Exemplary materials for the sacrificial layer 51 include SiN and the low-k film (SiOF and SiOC). The material for the sacrificial layer 51 needs to be the one that can be etched selectively with respect to the materials for the upper interlayer dielectric film ILD3, the hydrogen barrier film 30, and the upper electrode UE.

The sacrificial layer 51 is deposited so as to close the opening of the trench Tr, and needs not to be filled to the bottom of the trench Tr. Accordingly, voids can be generated in the trench Tr after the sacrificial layer 51 is formed. Such voids in the trench Tr are rather preferable because the sacrificial layer 51 is easily removed in the subsequent step.

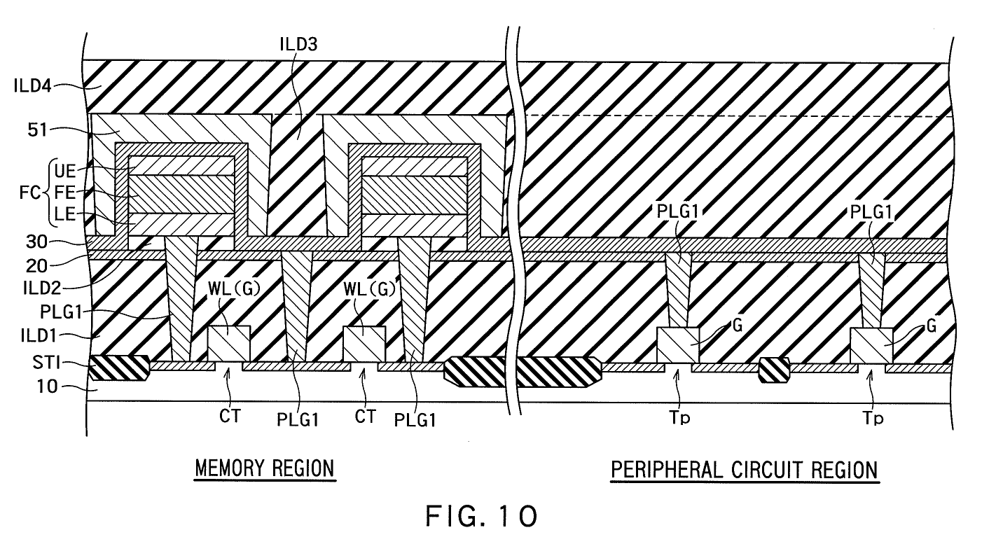

Next, as shown in FIG. 10, the upper interlayer dielectric film ILD4 is deposited on the upper interlayer dielectric film ILD3 and the sacrificial layer 51. Exemplary materials for the upper interlayer dielectric film ILD4 include P-TEOS, O₃-TEOS, and Al₂O₃.

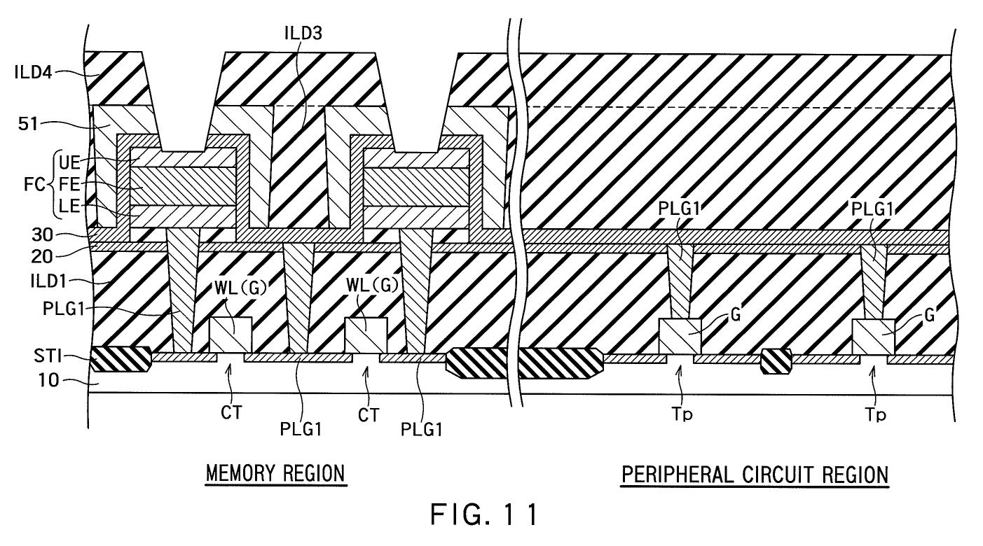

A contact hole CH1 is then formed by the lithography and RIE so as to pass through the upper interlayer dielectric films ILD4 and ILD3, the sacrificial layer 51, and the hydrogen barrier film 30 for reaching the upper electrode UE, as shown in FIG. 11.

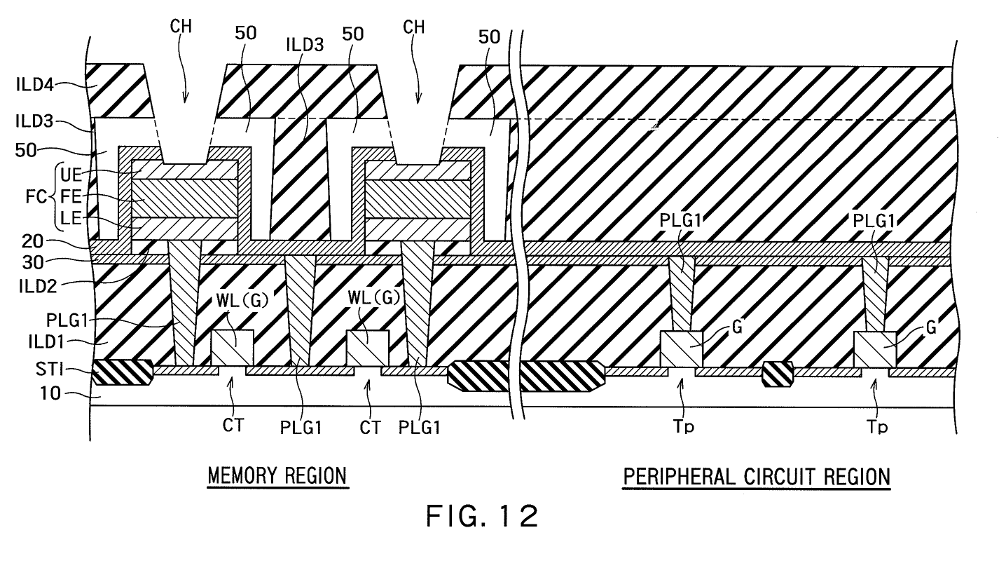

Next, as shown in FIG. 12, the sacrificial layer 51 is removed through the contact hole CH1. The sacrificial layer 51 is made of a material capable of being removed selectively with respect to the hydrogen barrier film 30 and the upper interlayer dielectric films ILD3 and ILD4. For example, when the hydrogen barrier film 30 is made of Al₂O₃, the upper interlayer dielectric films ILD3 and ILD4 are made of P-TEOS, O₃-TEOS, SOG, or the low-k film (SiOF, SiOC), and the upper electrode UE is made of Pt, Ir, IrO₂, SRO, Ru, or RuO₂, the sacrificial layer 51 can be made of SiN. In this case, the sacrificial layer 51 can be wet etched using a thermal phosphoric acid solution.

For example, when the hydrogen barrier film 30 is made of Al₂O₃, the upper interlayer dielectric films ILD3 and ILD4 are made of P-TEOS, O₃-TEOS, or SOG, and the upper electrode UE is made of Pt, Ir, IrO₂, SRO, Ru, or RuO₂, the sacrificial layer 51 can be made of the low-k film (SiOF or SiOC). In this case, the sacrificial layer 51 can be removed selectively by plasma etching.

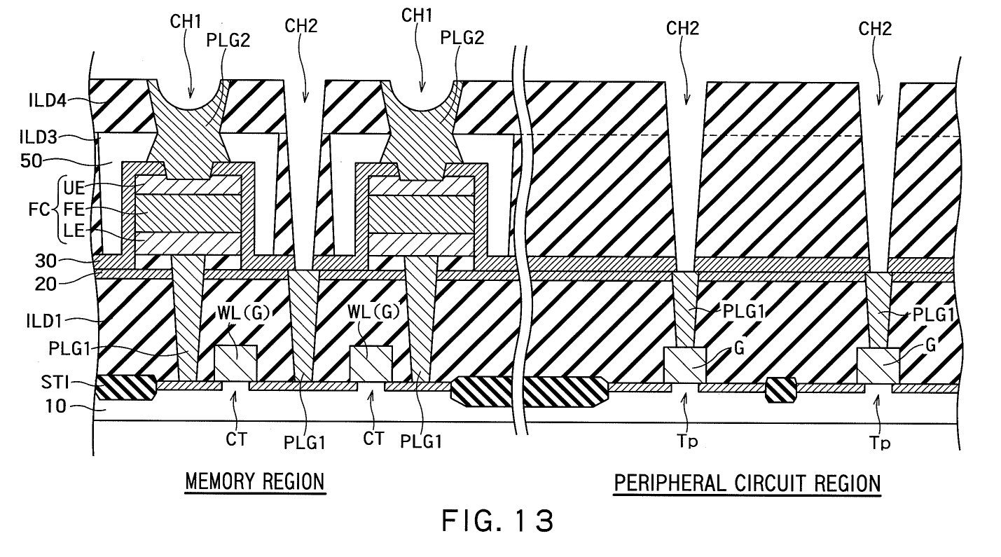

A metallic material for the second contact plug PLG2 is then buried in the contact hole CH1 by sputtering. As shown in FIG. 13, the metallic material for the second contact plug PLG2 is sputtered so as to close the opening of the gap 50 while maintaining a space in the gap 50. The metallic material for the second contact plug PLG2 includes any of W, Al, TiN, Cu, Ti, Ta, and TaN, for example.

Because the sputtering does not generate hydrogen, the ferroelectric capacitor FC is not deteriorated during this step. The metallic material for the second contact plug PLG2 on the upper interlayer dielectric film ILD4 is removed by the CMP. Thus, the second contact plug PLG2 is formed.

Next, as shown in FIG. 13, a contact hole CH2 is formed between the ferroelectric capacitors FC adjacent to each other in a direction the bit line BL extends. The contact hole CH2 is formed on the first contact plug PLG1. The contact hole CH2 is also formed on the contact plug PLG1 in the peripheral circuit region.

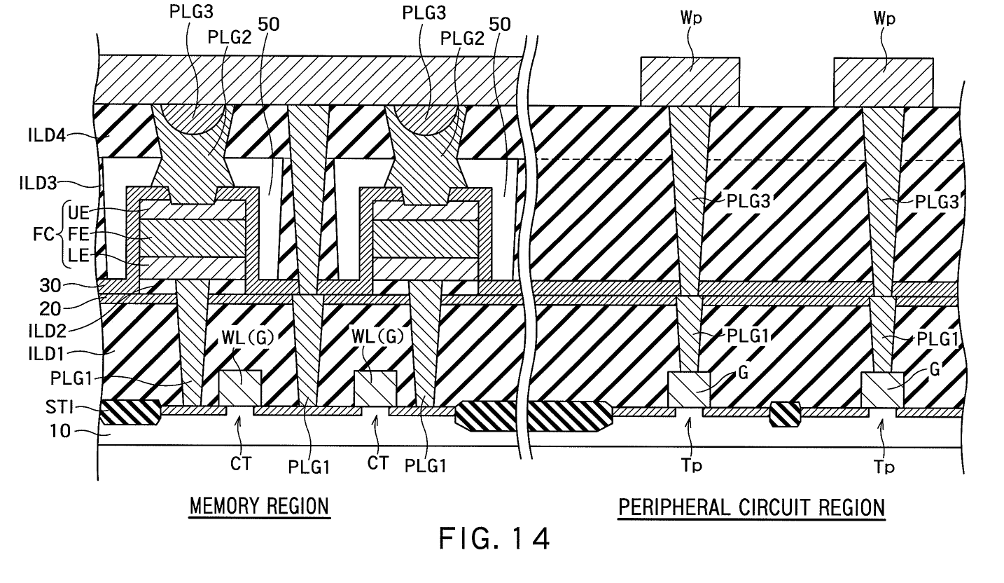

Next, as shown in FIG. 14, a metallic material for the third contact plug PLG3 is buried in the contact holes CH1 and CH2 by MO-CVD or sputtering. The metallic material for the third contact plug PLG3 includes any of W, Al, TiN, Cu, Ta, and TaN, for example. The MO-CVD generates hydrogen. However, the ferroelectric capacitor FC is covered by the hydrogen barrier films 20 and 30 and the second contact plug PLG2. The opening of the gap 50 is closed by the second contact plug PLG2. Thus, the deterioration of the ferroelectric capacitor FC caused by hydrogen can be suppressed.

The contact hole CH2 and the third contact plug PLG3 shown in FIG. 13 can be formed before forming the contact hole CH and the gap 50 shown in FIG. 12. In this case, even if the gap 50 connects to the contact hole CH2, a material of the third contact plug PLG3 would not bury the gap 50, since the third contact plug PLG3 is already formed.

Further, as shown in FIG. 14, a local interconnection LIC is formed on the third contact plug PLG3. An interconnection Wp is formed at the same time on the third contact plug PLG3 in the peripheral circuit region. An interlayer dielectric film (not shown) is further deposited and the ferroelectric random access memory of the first embodiment is thus completed.

In the first embodiment, the gap 50 is provided between the ferroelectric capacitor FC and the surrounding upper interlayer dielectric films ILD3 and ILD4. The gap 50 can absorb and relieve the stresses applied to the ferroelectric capacitor FC. Thus, the deterioration of the polarization characteristics of the ferroelectric capacitor FC can be suppressed.

In the first embodiment, a width of the gap 50 can be narrow as long as the sacrificial layer 51 can be etched. The sacrificial layer 51 needs not to be filled completely in the gap 50. Instead, the sacrificial layer 51 closes merely the opening of the gap 50. To etch the sacrificial layer 51 easily, it is preferable that the sacrificial layer 51 be not filled completely in the gap 50 and voids be generated in the sacrificial layer 51. To allow the second contact plug PLG2 to easily close the opening of the gap 50 easily, the width of the gap 50 is preferably narrow.

### Second Embodiment

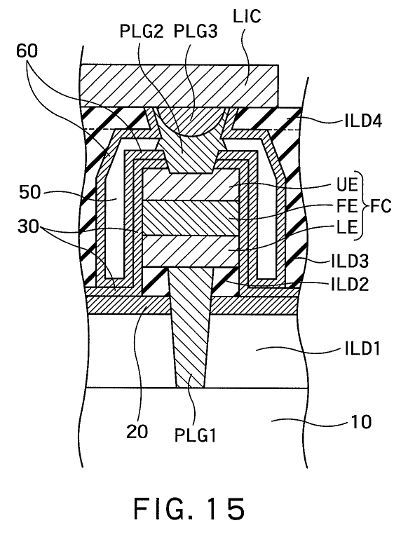

FIG. 15 is a cross-sectional view showing a configuration of a ferroelectric capacitor according to a second embodiment of the present invention. Only the ferroelectric capacitor is shown in FIG. 15 and the cell transistor is omitted. The second embodiment is provided with a hydrogen barrier film 60 covering an inner wall of the gap 50. The hydrogen barrier film 60 is also formed on walls of the upper interlayer dielectric films ILD3 and ILD4 in the gap 50. Other configurations of the second embodiment can be identical to those of the first embodiment.

The hydrogen barrier film 60 is made of, e.g., Al₂O₃ by ALD (Atomic Layer Deposition). Because the hydrogen barrier film 60 covers the inner wall of the gap 50, the deterioration of the ferroelectric capacitor FC can be further suppressed.

In the second embodiment, it is preferably that the total thickness of the hydrogen barrier films 30 and 60 on the side surface of the ferroelectric capacitor FC and the hydrogen barrier film 60 on the side surfaces of the upper interlayer dielectric films ILD3 and ILD4 be sufficient to suppress entering hydrogen. The thicknesses of the hydrogen barrier films 30 and 60 on the side surface of the ferroelectric capacitor FC can be reduced by the thickness of the hydrogen barrier film 60 on the side surfaces of the upper interlayer dielectric films ILD3 and ILD4. This leads to reduced stresses applied to the ferroelectric capacitor FC.

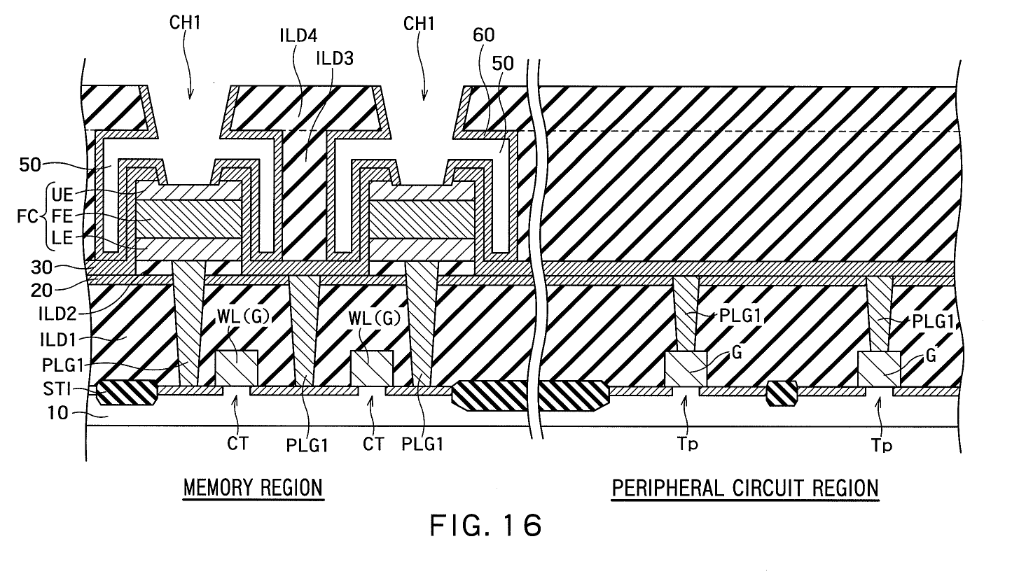

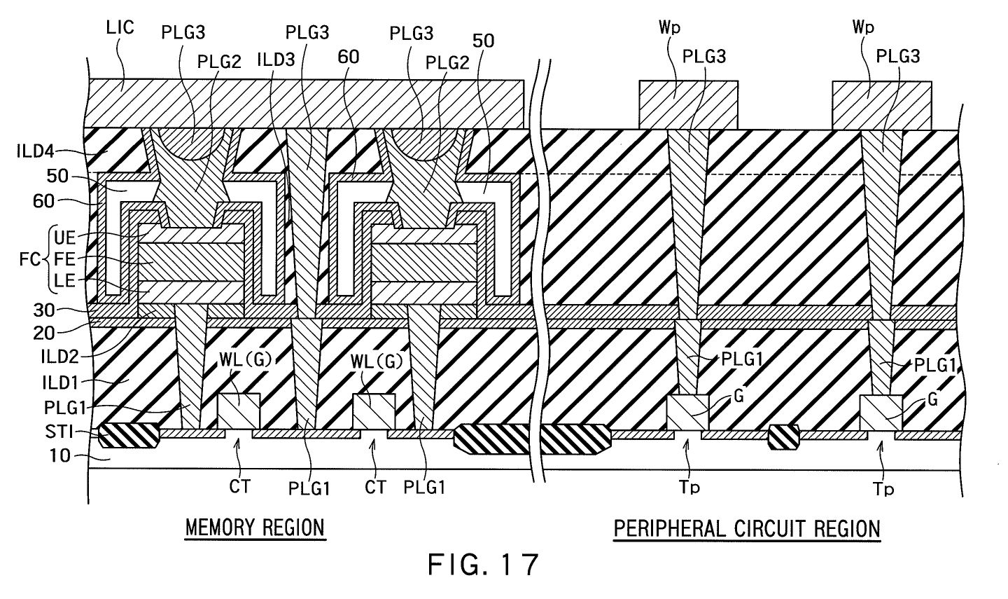

FIGS. 16 and 17 are cross-sectional views showing a manufacturing method of the ferroelectric capacitor FC according to the second embodiment. These drawings show the memory region and the peripheral circuit region side by side. After the steps shown in FIGS. 3 to 12, the hydrogen barrier film 60 is deposited on the inner wall of the gap 50 by the ALD as shown in FIG. 16. The hydrogen barrier film 60 is deposited not only on the side surface of the ferroelectric capacitor FC (hydrogen barrier film 30) but also on the walls of the upper interlayer dielectric films ILD3 and ILD4. The hydrogen barrier film 60 is then etched back in such a manner that the upper electrode UE is exposed on the bottom of the contact hole CH1.

The metallic material for the second contact plug PLG2 is then buried in the contact hole CH1. As shown in FIG. 17, the metallic material for the second contact plug PLG2 is sputtered so as to close the opening of the gap 50 while maintaining the space in the gap 50. The material for the second contact plug PLG2 and the direction the plug is to be formed are the same as those in the first embodiment.

The contact hole CH2, the third contact plug PLG3, and the local interconnection LIC are then formed. Materials therefor and methods of forming them are the same as those in the first embodiment.

When the upper interlayer dielectric films ILD3 and ILD4 are made of plasma TEOS in the second embodiment, hydrogen is generated. Thus, before the upper interlayer dielectric films ILD3 and ILD4 are formed, the hydrogen barrier film 30 needs to cover the side and top surfaces of the ferroelectric capacitor FC. When the upper interlayer dielectric films ILD3 and ILD4 are made of ozone TEOS, however, hydrogen is not generated. In this case, the hydrogen barrier film 30 needs not to be provided. The hydrogen barrier film 60 covers directly the side surface of the ferroelectric capacitor FC.

### Third Embodiment

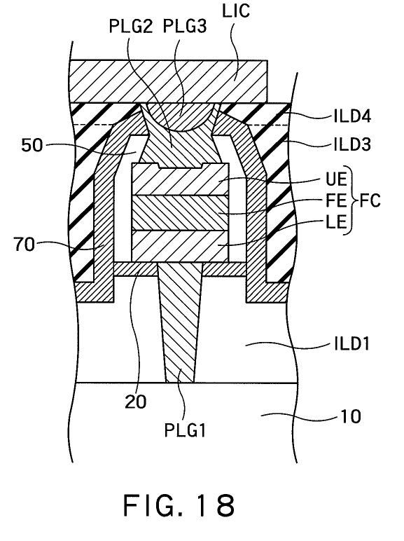

FIG. 18 is a cross-sectional view showing a configuration of a ferroelectric capacitor according to a third embodiment of the present invention. With reference to FIG. 18, only the ferroelectric capacitor is shown and the cell transistor is omitted. According to the third embodiment, the hydrogen barrier film is not provided on the side surface of the ferroelectric capacitor FC. A hydrogen barrier film 90 covering the walls of the upper interlayer dielectric films ILD3 and ILD4 among the inner walls of the gap 50 is provided. Other configurations of the third embodiment can be identical to those of the first embodiment.

The gap 50 is provided between the hydrogen barrier film 90 and the side surface of the ferroelectric capacitor FC. The side surface of the ferroelectric capacitor FC faces directly the gap 50. Thus, the stresses applied to the ferroelectric capacitor FC are further reduced.

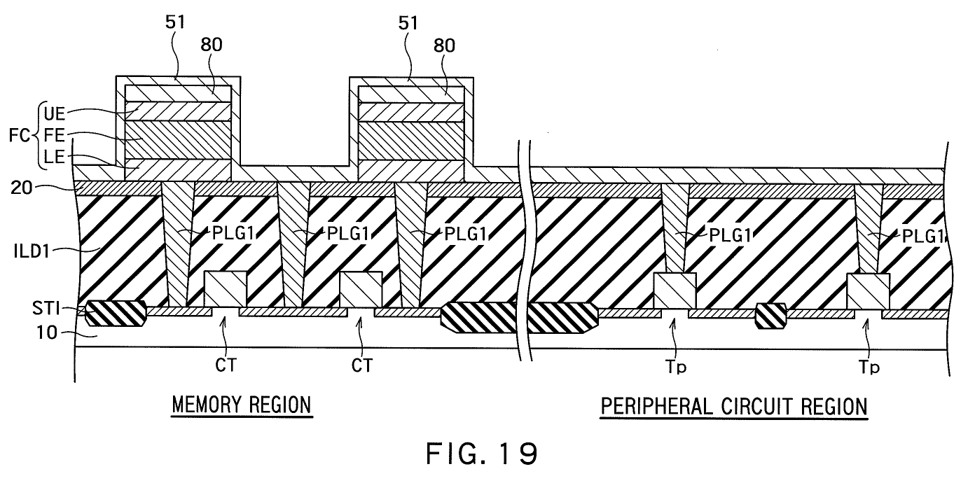

FIGS. 19 to 23 are cross-sectional views showing a manufacturing method of the third embodiment. The steps shown in FIGS. 3 to 5 are performed first. According to the third embodiment, after the hydrogen barrier film 20 is formed, the middle interlayer dielectric film ILD2 is not deposited. Instead, the ferroelectric capacitor FC is formed on the hydrogen barrier film 20. A mask material 80 used as a mask when the ferroelectric capacitor FC is formed remains on the upper electrode UE.

Next, as shown in FIG. 19, the sacrificial layer 51 is deposited on the side surface of the ferroelectric capacitor FC, and top surfaces of the mask material 80, the hydrogen barrier film 20, and the first contact plug PLG1. The sacrificial layer 51 is preferably made of a material which is the same as that of the mask material 80.

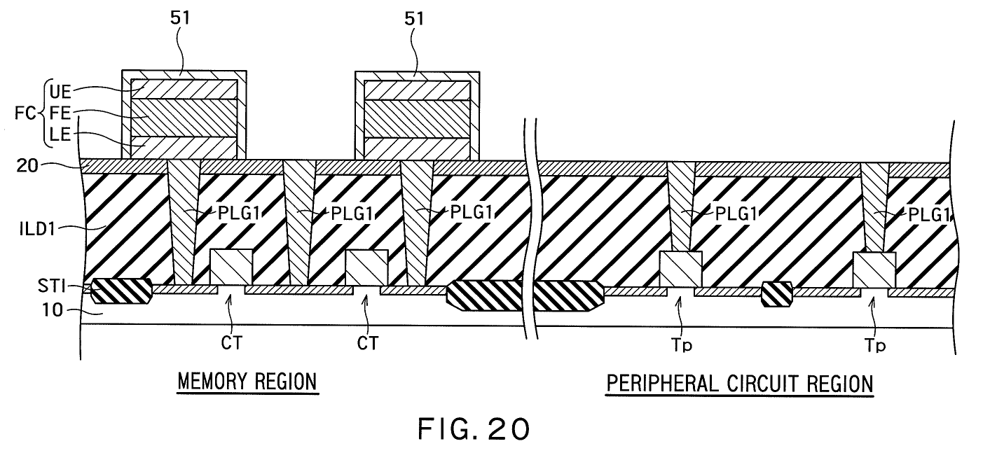

Next, as shown in FIG. 20, the sacrificial layer 51 is etched back until the top surface of the first contact plug PLG1 is exposed. While the sacrificial layer 51 on the upper electrode UE is also etched, the top surface of the upper electrode UE is kept covered by the mask material 80. The mask material 80 is made of the same material as the sacrificial layer 51 and functions as a sacrificial layer later. Thus, the mask material 80 and the sacrificial layer 51 will be collectively called “the sacrificial layer 51” for convenience.

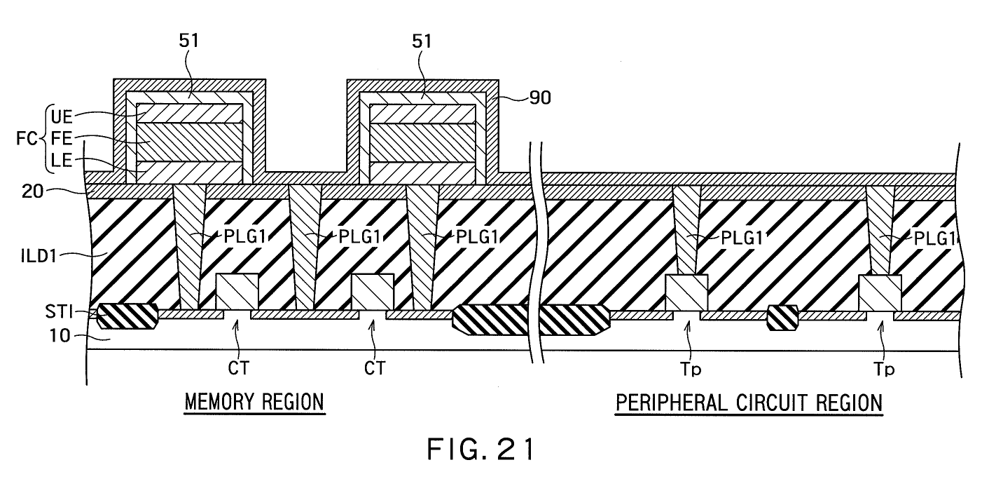

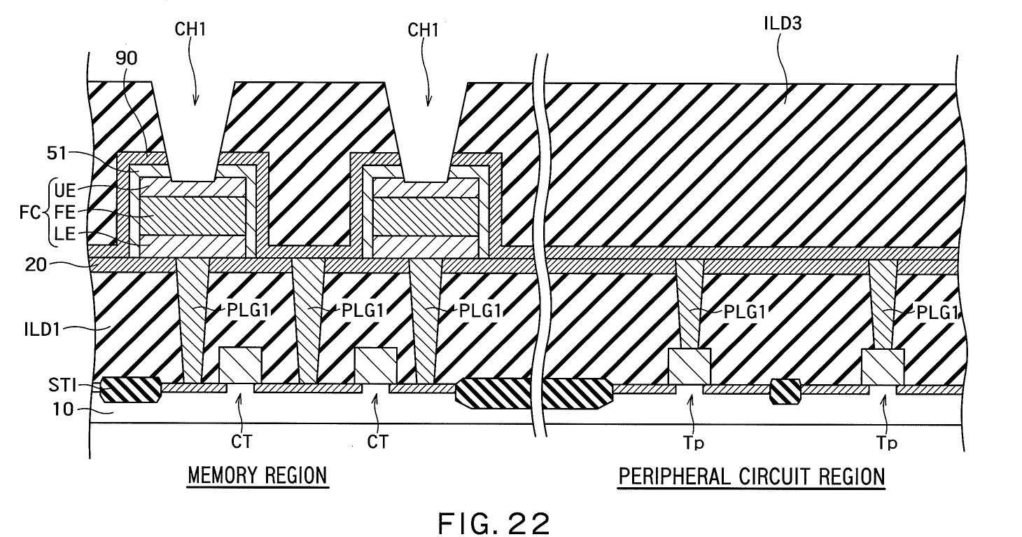

Next, as shown in FIG. 21, the hydrogen barrier film 90 is deposited on the sacrificial layer 51. As shown in FIG. 22, after the upper interlayer dielectric film ILD3 is deposited on the hydrogen barrier film 90, the contact hole CH1 is formed on the ferroelectric capacitor FC. The contact hole CH1 is formed so as to pass through the upper interlayer dielectric film ILD3, the hydrogen barrier film 90, and the sacrificial layer 51 for reaching the upper electrode UE.

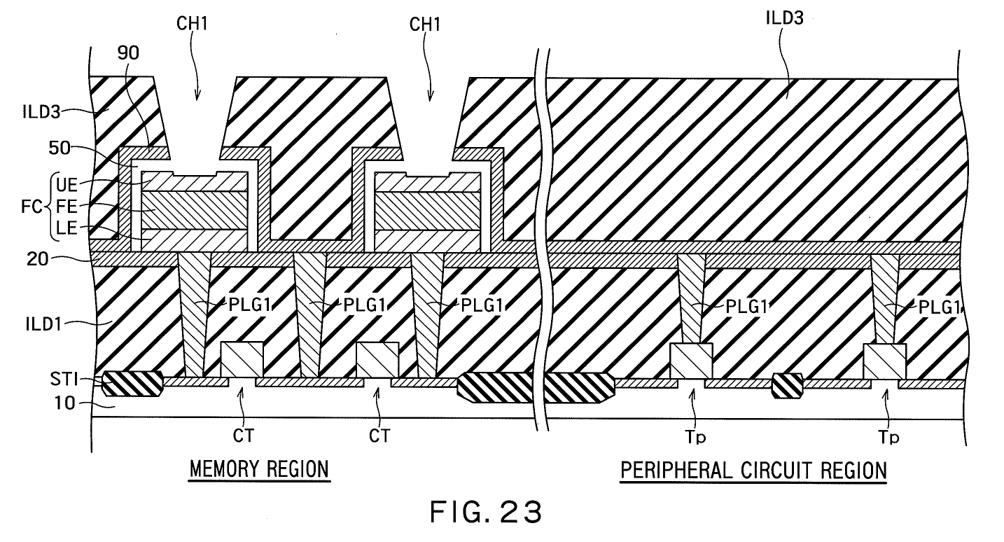

Next, as shown in FIG. 23, the sacrificial layer 51 is removed through the contact hole CH1. As in the first embodiment, the second contact plug PLG2, the contact hole CH2, the third contact plug PLG3, and the local interconnection LIC are then formed. The ferroelectric random access memory of the third embodiment is thus completed.

### Fourth Embodiment

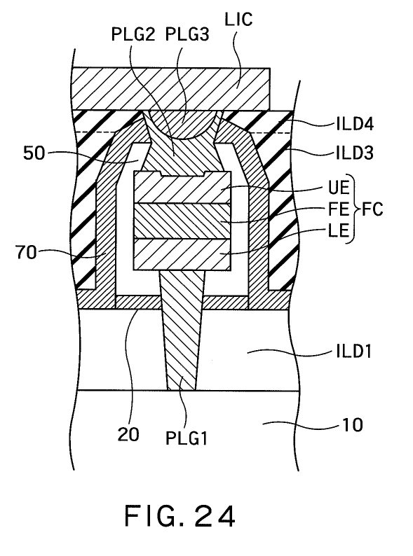

FIG. 24 is a cross-sectional view showing a configuration of a ferroelectric capacitor according to a fourth embodiment of the present invention. With reference to FIG. 24, only the ferroelectric capacitor is shown and the cell transistor is omitted. According to the fourth embodiment, a part of the bottom of the lower electrode LE for the ferroelectric capacitor FC faces the gap 50. Other configurations of the fourth embodiment can be identical to those of the third embodiment.

The gap 50 is provided between a part of the bottom of the lower electrode LE and the lower interlayer dielectric film ILD1, as well as between a part of the top surface of the upper electrode UE and the upper interlayer dielectric films ILD3 and ILD4. Thus, the stresses applied to the ferroelectric capacitor FC are further reduced.

A manufacturing method of the fourth embodiment is described below. As shown in FIG. 19, the ferroelectric capacitor FC is provided directly on the hydrogen barrier film 20 in the third embodiment. In the fourth embodiment, however, the middle interlayer dielectric film ILD2 is provided on the hydrogen barrier film 20 and the ferroelectric capacitor FC is provided on the middle interlayer dielectric film ILD2. When the sacrificial layer 51 is etched, the middle interlayer dielectric film ILD2 immediately under the lower electrode LE is also removed at the same time. Other steps in the manufacturing method of the fourth embodiment are the same as those of the third embodiment. In this way, the ferroelectric random access memory of the fourth embodiment can be formed.

In the third and fourth embodiments, after the sacrificial layer 51 and/or the middle interlayer dielectric film ILD2 is removed, the hydrogen barrier film 60 can be deposited on the inner wall of the gap 50 by the ALD. At this time, the hydrogen barrier film 60 is applied thinly also on the side surface of the ferroelectric capacitor FC. Although the stress of the hydrogen barrier film 60 is applied to the ferroelectric capacitor FC, the deterioration of the ferroelectric capacitor FC caused by hydrogen can be controlled better.

### Fifth Embodiment

The gap 50 can be provided for every ferroelectric capacitor FC in the first to fourth embodiments. Alternatively, the gap 50 can be shared by a plurality of ferroelectric capacitors FC. In such a case, the gap 50 is provided to be common to the ferroelectric capacitors FC adjacent to each other in a direction the word line WL extends.

The contact plug PLG3 connecting the local interconnection LIC to the first contact plug PLG1 is provided between the ferroelectric capacitors FC adjacent to each other in a direction the bit line BL extends. Thus, the gap 50 cannot be made common to the ferroelectric capacitors FC adjacent to each other in the direction the bit line BL extends.

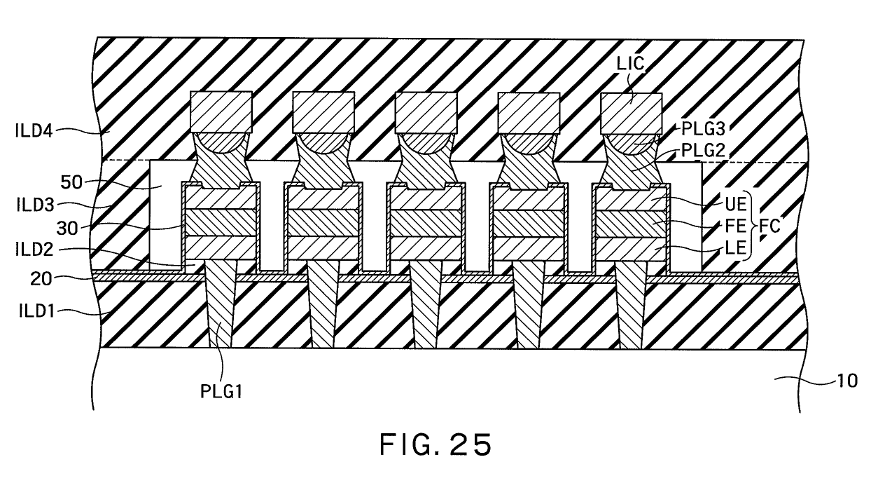

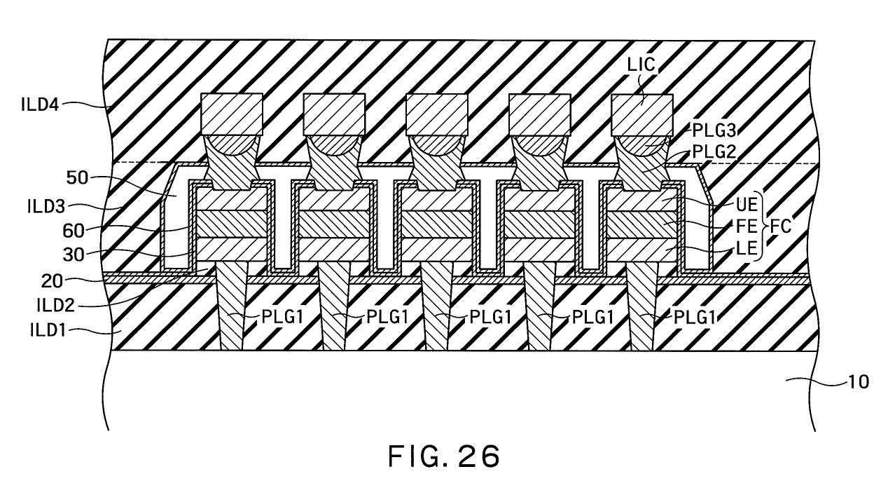

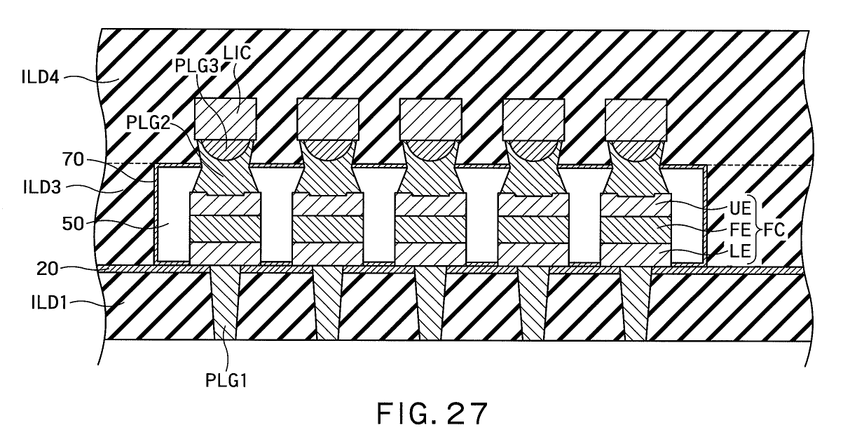

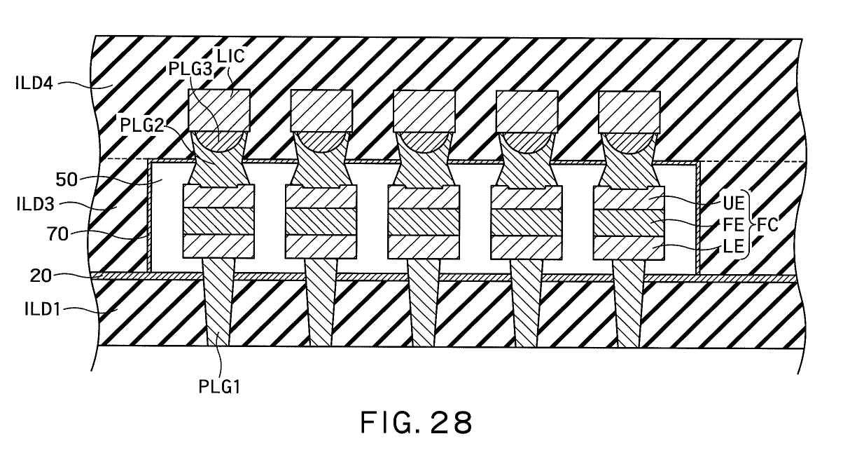

FIGS. 25 to 28 are cross-sectional views showing the ferroelectric capacitors FC that are adjacent to each other in the direction the word line WL extends and share the gap 50 for the first to fourth embodiments, respectively. The gap 50 is provided to communicate around the ferroelectric capacitors FC adjacent to each other in the direction the word line WL extends. Because the gap 50 is shared by the ferroelectric capacitors FC, the ferroelectric random access memory can be further downscaled. Moreover, the sacrificial layer 51 is removed easily.

1. A semiconductor memory device comprising:
a semiconductor substrate;
a ferroelectric capacitor comprising an upper electrode, a ferroelectric film, and a lower electrode above the semiconductor substrate; and
an upper interlayer dielectric film surrounding a periphery of the ferroelectric capacitor, wherein
a gap is between the ferroelectric capacitor and the upper interlayer dielectric film.

2. The device of claim 1 further comprising:
a transistor on the semiconductor substrate;
a lower interlayer dielectric film on the transistor; and
a contact plug in the lower interlayer dielectric film, wherein
the ferroelectric capacitor is on the lower interlayer dielectric film, and
the contact plug is configured to electrically connect the lower electrode to the transistor.

3. The device of claim 1 further comprising:
a hydrogen barrier film over a side surface of the ferroelectric capacitor, wherein
the gap is between the hydrogen barrier film and the upper interlayer dielectric film.

4. The device of claim 2 further comprising:
a hydrogen barrier film over a side surface of the ferroelectric capacitor, wherein
the gap is between the hydrogen barrier film and the upper interlayer dielectric film.

5. The device of claim 1 further comprising:
a hydrogen barrier film over an inner wall of the gap on a side of the upper interlayer dielectric film.

6. The device of claim 2 further comprising:
a hydrogen barrier film over an inner wall of the gap on a side of the upper interlayer dielectric film.

7. The device of claim 1 further comprising:
a hydrogen barrier film over a wall of the upper interlayer dielectric film among inner walls of the gap, wherein
the gap is between the hydrogen barrier film and the side surface of the ferroelectric capacitor.

8. The device of claim 2 further comprising:
a hydrogen barrier film over a wall of the upper interlayer dielectric film among inner walls of the gap, wherein
the gap is between the hydrogen barrier film and the side surface of the ferroelectric capacitor.

9. The device of claim 2, wherein the gap is between a portion of a bottom of the lower electrode and the lower interlayer dielectric film and between a portion of a top surface of the upper electrode and the upper interlayer dielectric film.

10. The device of claim 1, further comprising:
a plurality of the ferroelectric capacitors, wherein
the gap is shared by the ferroelectric capacitors.

11. The device of claim 2, further comprising:
a plurality of the ferroelectric capacitors, wherein
the gap is shared by the ferroelectric capacitors.

12. The device of claim 3, further comprising:
a plurality of the ferroelectric capacitors, wherein
the gap is shared by the ferroelectric capacitors.

13. The device of claim 5, further comprising:
a plurality of the ferroelectric capacitors, wherein
the gap is shared by the ferroelectric capacitors.

14. A method of manufacturing a semiconductor memory device comprising:
forming a transistor on a semiconductor substrate;
forming a lower interlayer dielectric film over the transistor;
forming a first contact plug passing through the lower interlayer dielectric film to be connected to the transistor;
forming a ferroelectric capacitor comprising an upper electrode, a ferroelectric film, and a lower electrode on the first contact plug;
forming a first hydrogen barrier film on side and top surfaces of the ferroelectric capacitor;
depositing a first upper interlayer dielectric film on the first hydrogen barrier film;
etching the first upper interlayer dielectric film in such a manner that a trench is formed around the ferroelectric capacitor;
burying a sacrificial layer in the trench;
depositing a second upper interlayer dielectric film on the sacrificial layer;
forming a contact hole passing through the second upper interlayer dielectric film, the sacrificial layer, and the first hydrogen barrier film, the contact hole being configured to reach the upper electrode;
removing the sacrificial layer selectively through the contact hole in order to form a gap between the first hydrogen barrier film and the first and the second upper interlayer dielectric films; and
forming a contact plug closing an opening of the gap.

15. The method of claim 14 further comprising:
depositing a second hydrogen barrier film on an inner wall of the gap after forming the gap.

16. A method of manufacturing a semiconductor memory device comprising:
forming a transistor on a semiconductor substrate;
forming a lower interlayer dielectric film over the transistor;
forming a first contact plug passing through the lower interlayer dielectric film to be connected to the transistor;
forming a ferroelectric capacitor comprising an upper electrode, a ferroelectric film, and a lower electrode on the first contact plug;
forming a sacrificial layer on side and top surfaces of the ferroelectric capacitor;
depositing the first hydrogen barrier film on the sacrificial layer;
depositing an upper interlayer dielectric film on the first hydrogen barrier film;
forming a contact hole passing through the upper interlayer dielectric film, the first hydrogen barrier film, and the sacrificial layer, the contact hold being configured to reach the upper electrode;
removing the sacrificial layer selectively through the contact hole in order to form a gap between a side surface of the ferroelectric capacitor and the first hydrogen barrier film; and
forming a contact plug closing an opening of the gap.

17. The method of claim 16 further comprising:
depositing a second hydrogen barrier film on an inner wall of the gap after forming the gap.

18. The method of claim 16 further comprising:
forming a lower barrier film on the lower interlayer dielectric film;
depositing a middle interlayer dielectric film on the lower barrier film;
forming the ferroelectric capacitor on the first contact plug and the middle interlayer dielectric film; and
removing the middle interlayer dielectric film under the ferroelectric capacitor at the same time when the sacrificial layer is removed.

19. The method of claim 18 further comprising:
depositing a second hydrogen barrier film on an inner wall of the gap after forming the gap.
